(19) United States
(12) Patent Application Publication
(10) Pub. No.: US 2018/0052566 A1
(43) Pub. Date: Feb. 22, 2018

(54) COORDINATE INPUT APPARATUS AND COORDINATE POSITION CALCULATING METHOD

(71) Applicant: Toshiki Kobayashi, Kanagawa (JP)

(72) Inventor: Toshiki Kobayashi, Kanagawa (JP)

(73) Assignee: Ricoh Company, Ltd., Tokyo (JP)

(21) Appl. No.: 15/673,881

(22) Filed: Aug. 10, 2017

(30) Foreign Application Priority Data
Aug. 19, 2016 (JP) 2016-160930

(51) Int. Cl. G06F 3/042; G06F 3/01; G06F 3/0484; G06F 3/0482

(52) U.S. Cl. CPC G06F 3/0428; G06F 3/011; H05K 3/301; G06F 3/0482; G06F 3/04845; G06F 3/04842

(57) ABSTRACT

A coordinate input apparatus includes: an imaging circuit including an image sensor; a retroreflecting member disposed along a peripheral portion of a coordinate input area; an illuminating unit to emit light through the input area toward the retroreflecting member; a light emitting device disposed around the peripheral portion of the input area on a straight line passing through an optical center of the imaging circuit and a calibration coordinate position in the input area; and circuitry to control ON and OFF of the illuminating unit and the light emitting device, respectively, detect, when a coordinate position in the input area is pointed by a pointer, an imaging position of an image of the pointer on the image sensor, calculate the coordinate position by triangulation based on the imaging position and the installation angle, and calibrate the installation angle based on the imaging position and the calibration coordinate position.

### CROSS-REFERENCE TO RELATED APPLICATION

This patent application is based on and claims priority pursuant to 35 U.S.C. §119(a) to Japanese Patent Application No. 2016-160930 filed on Aug. 19, 2016, in the Japan Patent Office, the entire disclosure of which is hereby incorporated by reference herein.

### BACKGROUND

### Technical Field

The present invention relates to a coordinate input apparatus and a coordinate position calculating method.

### Description of the Related Art

In the past, an apparatus has been provided which includes light source units around the periphery of a coordinate input area, obtains the information of an emitted light interception point of a pointer (e.g., a human finger or a stylus pen), and calculates by triangulation the information of an insertion position of the pointer in the coordinate input area.

For example, there is an electronic whiteboard system including fluorescent lamps around the periphery of the coordinate input area as the light source units. The electronic whiteboard system displays, on a display thereof, a touch point at a known coordinate position to prompt a user to touch the touch point with the pointer to perform calibration.

### SUMMARY

In one embodiment of this invention, there is provided an improved coordinate input apparatus that includes, for example, an imaging circuit, a retroreflecting member, an illuminating unit, a light emitting device, and circuitry. The imaging circuit includes an image sensor, and is disposed on a baseline parallel to one side of a peripheral portion of a two-dimensional coordinate input area including a calibration coordinate position virtually defined for calibration, with an optical axis of the imaging circuit forming a predetermined installation angle with the baseline. The retroreflecting member is disposed along the peripheral portion of the coordinate input area. The illuminating unit is disposed at a same position as a position of the imaging circuit to emit light traveling through the coordinate input area toward the retroreflecting member. The light emitting device is disposed around the peripheral portion of the coordinate input area on a straight line passing through an optical center of the imaging circuit and the calibration coordinate position. The circuitry controls turn-on and turn-off of the illuminating unit and the light emitting device, respectively. When a specific two-dimensional coordinate position in the coordinate input area is pointed by a pointer, the circuitry detects an imaging position of an image of the pointer on the image sensor of the imaging circuit, calculates the specific two-dimensional coordinate position in the coordinate input area by triangulation based on the imaging position and the installation angle, and calibrates the installation angle of the imaging circuit based on the imaging position and the calibration coordinate position.

In one embodiment of this invention, there is provided an improved coordinate input apparatus that includes, for example, an imaging circuit, a retroreflecting member, an illuminating unit, an interceptor, and circuitry. The imaging circuit includes an image sensor, and is disposed on a baseline parallel to one side of a peripheral portion of a two-dimensional coordinate input area including a calibration coordinate position virtually defined for calibration, with an optical axis of the imaging circuit forming a predetermined installation angle with the baseline. The retroreflecting member is disposed along the peripheral portion of the coordinate input area. The illuminating unit is disposed at a same position as a position of the imaging circuit to emit light traveling through the coordinate input area toward the retroreflecting member. The interceptor is disposed around the peripheral portion of the coordinate input area to intercept a position on the retroreflecting member intersecting a straight line passing through an optical center of the imaging circuit and the calibration coordinate position. The circuitry controls turn-on and turn-off of the illuminating unit and the interceptor, respectively. When a specific two-dimensional coordinate position in the coordinate input area is pointed by a pointer, the circuitry detects an imaging position of an image of the pointer on the image sensor of the imaging circuit, calculates the specific two-dimensional coordinate position in the coordinate input area by triangulation based on the imaging position and the installation angle, and calibrates the installation angle of the imaging circuit based on the imaging position and the calibration coordinate position.

In one embodiment of this invention, there is provided an improved coordinate position calculating method executed by a coordinate input apparatus that includes, for example, an imaging circuit, a retroreflecting member, an illuminating unit, and a light emitting device. The imaging circuit includes an image sensor, and is disposed on a baseline parallel to one side of a peripheral portion of a two-dimensional coordinate input area including a calibration coordinate position virtually defined for calibration, with an optical axis of the imaging circuit forming a predetermined installation angle with the baseline. The retroreflecting member is disposed along the peripheral portion of the coordinate input area. The illuminating unit is disposed at a same position as a position of the imaging circuit to emit light traveling through the coordinate input area toward the retroreflecting member. The light emitting device is disposed around the peripheral portion of the coordinate input area on a straight line passing through an optical center of the imaging circuit and the calibration coordinate position. The coordinate position calculating method includes controlling turn-on and turn-off of the illuminating unit, controlling turn-on and turn-off of the light emitting device, detecting, when a specific two-dimensional coordinate position in the coordinate input area is pointed by a pointer, an imaging position of an image of the pointer on the image sensor of the imaging circuit, calculating the specific two-dimensional coordinate position in the coordinate input area by triangulation based on the imaging position and the installation angle, and calibrating the installation angle of the imaging circuit based on the imaging position and the calibration coordinate position.

### BRIEF DESCRIPTION OF THE SEVERAL VIEWS OF THE DRAWINGS

A more complete appreciation of the disclosure and many of the attendant advantages and features thereof can be readily obtained and understood from the following detailed description with reference to the accompanying drawings, wherein:

FIG. 1 is a schematic diagram illustrating a configuration of a coordinate input apparatus of a first embodiment of the present invention;

FIG. 2 is a functional block diagram of the coordinate input apparatus of the first embodiment;

FIG. 3 is a hardware configuration diagram of the coordinate input apparatus of the first embodiment;

FIG. 4 is a flowchart illustrating a coordinate position calculation process of the first embodiment;

FIGS. 5A and 5B are diagrams illustrating the coordinate position calculation process of the first embodiment;

FIG. 6 is a flowchart illustrating a first type of installation angle calibration process of the first embodiment;

FIGS. 7A and 7B are diagrams illustrating the first type of installation angle calibration process of the first embodiment;

FIG. 8 is a flowchart illustrating a second type of installation angle calibration process of the first embodiment;

FIG. 9 is a schematic diagram illustrating a configuration of a coordinate input apparatus of a second embodiment of the present invention;

FIG. 10 is a functional block diagram of the coordinate input apparatus of the second embodiment;

FIG. 11 is a flowchart illustrating a first type of installation angle calibration process of the second embodiment; and

FIG. 12 is a flowchart illustrating a second type of installation angle calibration process of the second embodiment.

The accompanying drawings are intended to depict embodiments of the present invention and should not be interpreted to limit the scope thereof. The accompanying drawings are not to be considered as drawn to scale unless explicitly noted.

### DETAILED DESCRIPTION

The terminology used herein is for the purpose of describing particular embodiments only and is not intended to be limiting of the present invention. As used herein, the singular forms “a”, “an” and “the” are intended to include the plural forms as well, unless the context clearly indicates otherwise.

In describing embodiments illustrated in the drawings, specific terminology is employed for the sake of clarity. However, the disclosure of this specification is not intended to be limited to the specific terminology so selected and it is to be understood that each specific element includes all technical equivalents that have a similar function, operate in a similar manner, and achieve a similar result.

Referring now to the accompanying drawings, wherein like reference numerals designate identical or corresponding parts throughout the several views, embodiments of the present invention will be described. Redundant description of identical or corresponding parts will be omitted where appropriate.

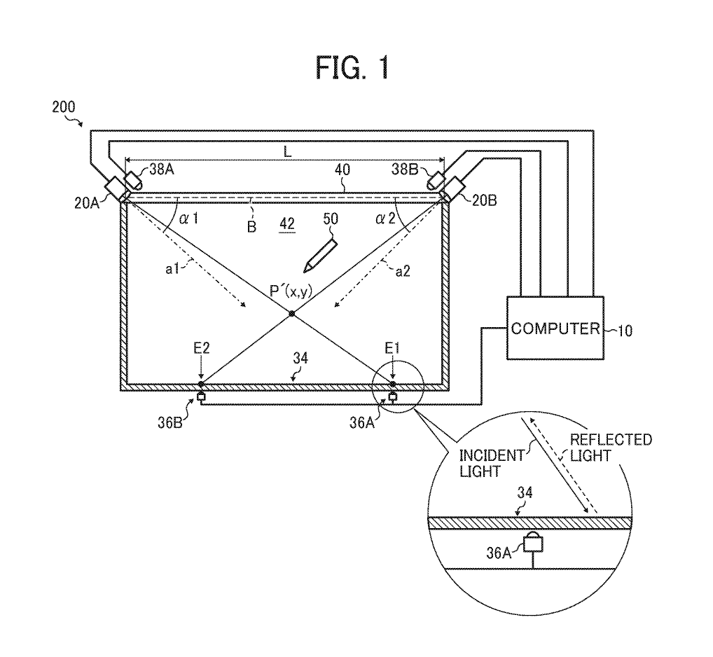

FIG. 1 schematically illustrates a configuration of a coordinate input apparatus 200 according to a first embodiment of the present invention.

As illustrated in FIG. 1, the coordinate input apparatus 200 of the first embodiment includes a display unit 40 with a rectangular display screen 42, two imaging units 20, i.e., a first imaging unit 20A and a second imaging unit 20B, a computer 10, and a retroreflecting member 34. The retroreflecting member 34 is disposed in a roughly U-shape around a peripheral portion of the display screen 42 excluding an upper side of the display screen 42 to surround a rectangular two-dimensional coordinate input area defined on the rectangular display screen 42. The computer 10, the first imaging unit 20A, the second imaging unit 20B, and the display unit 40 are mutually communicably connected by wire or radio. Herein, the retroreflecting member 34 is a reflecting member that reflects incident light toward the optical path of the incident light. Examples of such a reflecting member include a member formed of an array of multiple conical corner cubes.

The display unit 40 is a display, preferably a flat panel display. The display unit 40 displays an image output from the computer 10.

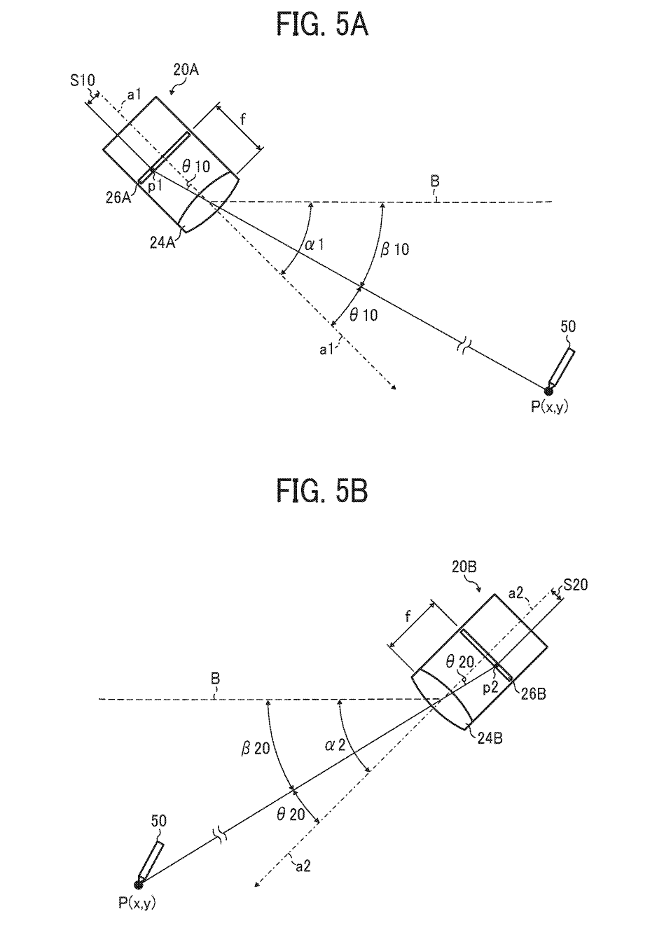

The first imaging unit 20A is a digital camera including an image forming optical system 24A and an image sensor 26A illustrated in FIG. 5A. Similarly, the second imaging unit 20B is a digital camera including an image forming optical system 24B and an image sensor 26B illustrated in FIG. 5B. Each of the image sensors 26A and 26B is preferably a line sensor having charge-coupled devices (CCDs) or complementary metal oxide semiconductors (CMOSs) arranged in a line. Herein, the first imaging unit 20A is fixed with an optical axis a1 of the image forming optical system 24A extending substantially parallel to a surface of the display screen 42 (i.e., a plane of the coordinate input area), and the optical axis a1 and a baseline B forming a predetermined installation angle α1 such that the angle of field of the image forming optical system 24A covers the entire coordinate input area. Similarly, the second imaging unit 20B is fixed with an optical axis a2 of the image forming optical system 24B extending substantially parallel to the surface of the display screen 42 (i.e., the plane of the coordinate input area), and the optical axis a2 and the baseline B forming a predetermined installation angle α2 such that the angle of field of the image forming optical system 24B covers the entire coordinate input area. The first imaging unit 20A and the second imaging unit 20B are spaced from each other by a predetermined distance L.

The coordinate input apparatus 200 of the first embodiment further includes two illuminating units 38, i.e., a first illuminating unit 38A and a second illuminating unit 38B, to emit probe light traveling through the coordinate input area defined on the display screen 42. As illustrated in FIG. 1, in the first embodiment, the first illuminating unit 38A is disposed at the same position as that of the first imaging unit 20A, and the second illuminating unit 38B is disposed at the same position as that of the second imaging unit 20B. Each of the first illuminating unit 38A and the second illuminating unit 38B radially emits the probe light to cover the entire coordinate input area. Examples of the illuminating units 38 include highly directional light emitting diode (LED) lamps. The first illuminating unit 38A is not necessarily required to be at exactly the same position as that of the first imaging unit 20A, as long as the first illuminating unit 38A is capable of radially emitting the probe light to cover the entire coordinate input area. Similarly, the second illuminating unit 38B is not necessarily required to be at exactly the same position as that of the second imaging unit 20B, as long as the second illuminating unit 38B is capable of radially emitting the probe light to cover the entire coordinate input area.

The coordinate input apparatus 200 of the first embodiment further includes two light emitting devices 36, i.e., a first light emitting device 36A and a second light emitting device 36B, disposed around the peripheral portion of the coordinate input area defined on the display screen 42. The light emitting devices 36 are preferably LED devices.

In the first embodiment, the first light emitting device 36A and the second light emitting device 36B are installed at respective predetermined positions around the peripheral portion of the coordinate input area. Specifically, as illustrated in FIG. 1, the first light emitting device 36A is installed at a position E1 on a straight line passing through the optical center of the first imaging unit 20A and a calibration coordinate position P′ (x, y). Further, the second light emitting device 36B is installed at a position E2 on a straight line passing through the optical center of the second imaging unit 20B and the calibration coordinate position P′ (x, y).

The computer 10 is an information processor that controls the light emission of the first light emitting device 36A and the second light emitting device 36B, executes calculation by triangulation based on the installation angles α1 and α2 and camera output signals from the first imaging unit 20A and the second imaging unit 20B, and calculates and outputs a two-dimensional coordinate position in the defined coordinate input area on the display screen 42 pointed by a given pointer 50, such as a stylus pen or a human finger. The computer 10 may be a dedicated built-in computer integrated with the coordinate input apparatus 200, or may be a personal computer.

In the first embodiment, the coordinate input apparatus 200 functions as an electronic whiteboard when displaying, on the display screen 42 of the display unit 40, the trajectory of the two-dimensional coordinate position calculated by the computer 10 as a drawn line. The coordinate input apparatus 200 further has a function of automatically calibrating the installation angle α1 of the first imaging unit 20A and the installation angle α2 of the second imaging unit 20B.

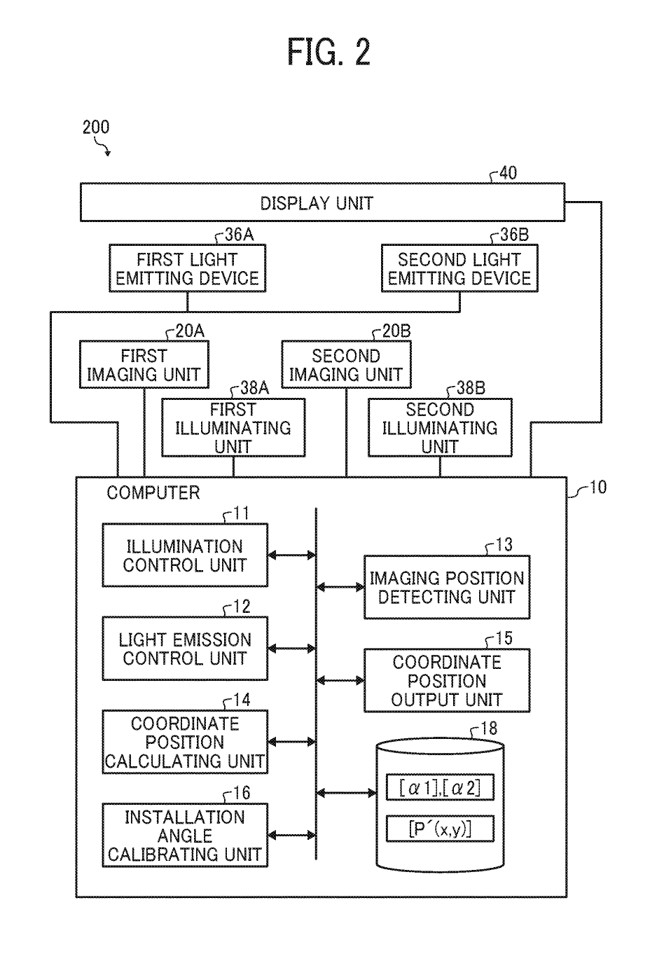

FIG. 2 illustrates functional blocks of the coordinate input apparatus 200 of the first embodiment. The computer 10 forming the coordinate input apparatus 200 includes an illumination control unit 11 that controls the first illuminating unit 38A and the second illuminating unit 38B, a light emission control unit 12 that controls the light emission of the first light emitting device 36A and the second light emitting device 36B, an imaging position detecting unit 13, a coordinate position calculating unit 14, a coordinate position output unit 15, an installation angle calibrating unit 16, each of which, or which are collectively, referred to as circuitry. The computer 10 further includes a storage area 18, which may be implemented by any desired memory that operates under control of the circuitry.

The light emission control unit 12 controls turn-on and turn-off of the first light emitting device 36A and the second light emitting device 36B. In the first embodiment, each of the installation positions of the first light emitting device 36A and the second light emitting device 36B is assigned with an installation position identifier (ID). The light emission control unit 12 is capable of individually controlling turn-on and turn-off of the first light emitting device 36A and turn-on and turn-off of the second light emitting device 36B based on the installation position ID.

If the pointer 50 is inserted in the coordinate input area, the imaging position detecting unit 13 detects respective imaging positions of the image of the pointer 50 on the image sensor 26A of the first imaging unit 20A and the image sensor 26B of the second imaging unit 20B.

The coordinate position calculating unit 14 calculates the two-dimensional coordinate position of the pointer 50 by triangulation based on the installation angles α1 and α2 and the respective imaging positions of the image of the pointer 50 on the first imaging unit 20A and the second imaging unit 20B.

The coordinate position output unit 15 outputs the two-dimensional coordinate position of the pointer 50 calculated by the coordinate position calculating unit 14 to a specified output destination, such as an external device or an application.

The installation angle calibrating unit 16 calibrates the installation angle α1 of the first imaging unit 20A and the installation angle α2 of the second imaging unit 20B.

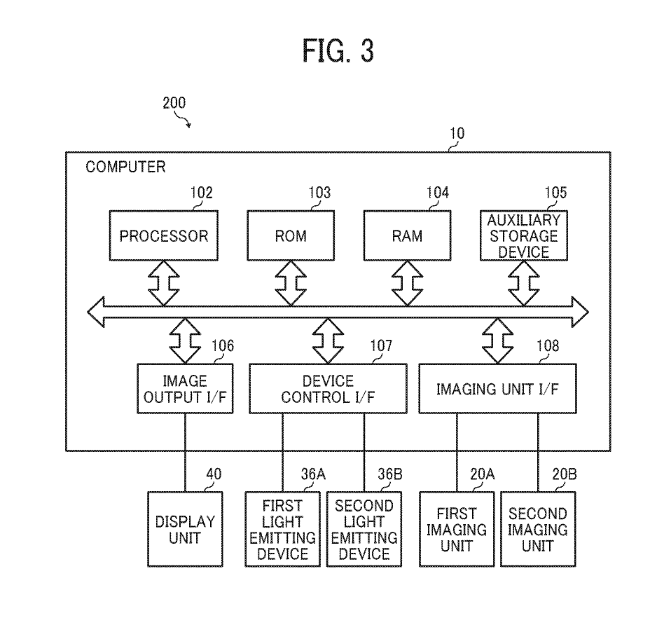

The storage area 18 is provided by an auxiliary storage device 105 of the computer 10 illustrated in FIG. 3. The storage area 18 stores the installation angle α1 of the first imaging unit 20A, the installation angle α2 of the second imaging unit 20B, and the calibration coordinate position P′ (x, y). The storage area 18 may also store a point image for displaying a point icon at the calibration coordinate position P′ (x, y).

Herein, the calibration coordinate position P′ (x, y) refers to a two-dimensional coordinate position virtually defined on the coordinate input area for calibration. A given position on the coordinate input area corresponding to the display screen 42 is previously defined as the calibration coordinate position P′ (x, y).

The installation position E1 of the first light emitting device 36A on the straight line passing through the optical center of the first imaging unit 20A and the calibration coordinate position P′ (x, y), as illustrated in FIG. 1, is assigned with an installation position ID IDE1 to indicate a first turn-off position. Similarly, the installation position E2 of the second light emitting device 36B on the straight line passing through the optical center of the second imaging unit 20B and the calibration coordinate position P′ (x, y) is assigned with an installation position ID IDE2 to indicate a second turn-off position.

In the coordinate input apparatus 200 of the first embodiment with the above-described functional configuration, the computer 10 executes a predetermined program to cause the coordinate input apparatus 200 to function as the respective units described above.

A hardware configuration of devices forming the coordinate input apparatus 200 of the first embodiment will now be described based on FIG. 3.

As illustrated in FIG. 3, the computer 10, which is an information processor forming the coordinate input apparatus 200 of the first embodiment, includes a processor 102, a read only memory (ROM) 103, a random access memory (RAM) 104, the auxiliary storage device 105, an image output interface (I/F) 106, a device control I/F 107, and an imaging unit I/F 108. The processor 102 controls the operation of the entire coordinate input apparatus 200. The ROM 103 stores a boot program and a firmware program, for example. The RAM 104 provides an area for deploying programs for execution. The auxiliary storage device 105 stores the program for causing the coordinate input apparatus 200 to function as the above-described units, an operating system (OS), and a variety of data. The image output I/F 106 connects the computer 10 to the display unit 40. The device control I/F 107 connects the computer 10 to the first light emitting device 36A and the second light emitting device 36B. The imaging unit I/F 108 connects the computer 10 to the first imaging unit 20A and the second imaging unit 20B.

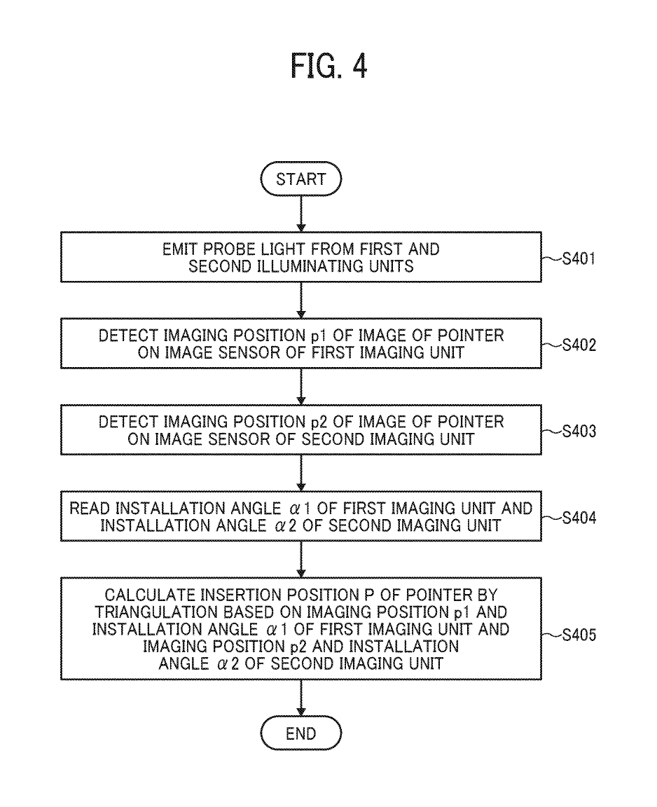

A coordinate position calculation process executed by the coordinate input apparatus 200 will now be described based on the flowchart of FIG. 4.

At step S401, the illumination control unit 11 first turns on the first illuminating unit 38A and the second illuminating unit 38B to emit the probe light therefrom. The probe light emitted from the first illuminating unit 38A and the second illuminating unit 38B travels parallel to the display screen 42, and is reflected by the retroreflecting member 34 disposed around the peripheral portion of the display screen 42. The reflected probe light is then received by the first imaging unit 20A and the second imaging unit 20B. If the pointer 50 is inserted in the coordinate input area in this state, the image of the pointer 50 is formed on each of the image sensor 26A of the first imaging unit 20A and the image sensor 26B of the second imaging unit 20B as a dark spot.

At step S402, the imaging position detecting unit 13 detects an imaging position p1 of the image of the pointer 50 on the image sensor 26A of the first imaging unit 20A, as illustrated in FIG. 5A.

FIG. 5A schematically illustrates a state in which the image of the pointer 50 inserted at an insertion position P (x, y) is formed on the image sensor 26A of the first imaging unit 20A via the image forming optical system 24A.

If the pointer 50 is not inserted in the coordinate input area, the light intensity distribution on the image sensor 26A is substantially uniform. If the pointer 50 is inserted in the coordinate input area, and if the image of the pointer 50 is formed on the image sensor 26A, the light intensity is reduced at the imaging position p1 on the image sensor 26A to form the dark spot, which appears at a peak point in a light intensity waveform of the camera output signal from the image sensor 26A. Based on the peak point in the light intensity waveform of the camera output signal from the image sensor 26A of the first imaging unit 20A, i.e., a point corresponding to the dark spot, the imaging position detecting unit 13 detects the imaging position p1 of the image of the pointer 50.

At step S403, the imaging position detecting unit 13 detects an imaging position p2 of the image of the pointer 50 on the image sensor 26B of the second imaging unit 20B, as illustrated in FIG. 5B.

FIG. 5B schematically illustrates a state in which the image of the pointer 50 inserted at the insertion position P (x, y) is formed on the image sensor 26B of the second imaging unit 20B via the image forming optical system 24B. Similarly as in the detection of the imaging position p1, the imaging position detecting unit 13 detects the imaging position p2 of the image of the pointer 50 based on a peak point in a light intensity waveform of the camera output signal from the image sensor 26B of the second imaging unit 20B, i.e., a point corresponding to the dark spot.

At step S404, the coordinate position calculating unit 14 reads the installation angle α1 of the first imaging unit 20A and the installation angle α2 of the second imaging unit 20B from the storage area 18.

At step S405, the coordinate position calculating unit 14 calculates the insertion position P (x, y) of the pointer 50, i.e., the two-dimensional coordinate position of the pointer 50 inserted in the coordinate input area, by triangulation based on the imaging position p1 and the installation angle α1 of the first imaging unit 20A and the imaging position p2 and the installation angle α2 of the second imaging unit 20B.

As illustrated in FIG. 5A, s10 represents the distance from the center of the image sensor 26A of the first imaging unit 20A to the center of the imaging position p1, and f represents the focal length of the image forming optical system 24A of the first imaging unit 20A. Further, θ10 represents the angle formed by a line segment connecting the imaging position p1 and the insertion position P (x, y) and the center line of the image sensor 26A, i.e., the optical axis a1 of the image forming optical system 24A. The angle θ10 is calculated from equation (1) given below:

θ10=tan⁻¹(s10/f) (1)

Further, an angle β10 formed by the line segment connecting the imaging position p1 and the insertion position P (x, y) and the baseline B is calculated from equation (2) given below with the installation angle α1 of the first imaging unit 20A:

β10=α1−θ10 (2)

Similarly, as illustrated in FIG. 5B, s20 represents the distance from the center of the image sensor 26B of the second imaging unit 20B to the center of the imaging position p2, and f represents the focal length of the image forming optical system 24B of the second imaging unit 20B. Further, θ20 represents the angle formed by a line segment connecting the imaging position p2 and the insertion position P (x, y) and the center line of the image sensor 26B, i.e., the optical axis a2 of the image forming optical system 24B. The angle θ20 is expressed by equation (3) given below:

θ20=tan⁻¹(s20/f) (3)

Further, an angle β20 formed by the line segment connecting the imaging position p2 and the insertion position P (x, y) and the baseline B is calculated from equation (4) given below with the installation angle α2 of the second imaging unit 20B:

β20=α2−θ20 (4)

Further, two-dimensional coordinates (x, y) of the insertion position P (x, y) of the pointer 50 are calculated from equations (5) and (6) given below by the principle of triangulation with the angles β10 and β20 calculated by the above-described procedures and the distance L in FIG. 1 between the center of the image forming optical system 24A of the first imaging unit 20A and the center of the image forming optical system 24B of the second imaging unit 20B:

x=L·tan β20/(tan β10+tan β20) (5)

y=x tan β10 (6)

In the first embodiment, the coordinate input apparatus 200 repeats the above-described execution of steps S401 to S405 at predetermined time intervals, and the coordinate position output unit 15 outputs the two-dimensional coordinates (x, y) calculated during the execution of the steps to the specified output destination. For example, if rendering software for the electronic whiteboard is specified as the output destination of the two-dimensional coordinates (x, y), the trajectory of the pointer 50 is displayed as a drawn line overlaid on contents displayed on the display screen 42.

Following the above description of the coordinate position calculation process executed by the coordinate input apparatus 200 of the first embodiment, an installation angle calibration process executed by the coordinate input apparatus 200 will now be described.

The installation angle α1 of the first imaging unit 20A and the installation angle α2 of the second imaging unit 20B may deviate from the values thereof stored in the storage area 18 for various reasons. If such deviation is left uncalibrated, the coordinate position calculating unit 14 will eventually fail to calculate the correct insertion position P (x, y) of the pointer 50. In the first embodiment, therefore, the coordinate input apparatus 200 executes the installation angle calibration process of calibrating the installation angle α1 of the first imaging unit 20A and the installation angle α2 of the second imaging unit 20B stored in the storage area 18. The installation angle calibration process has two types.

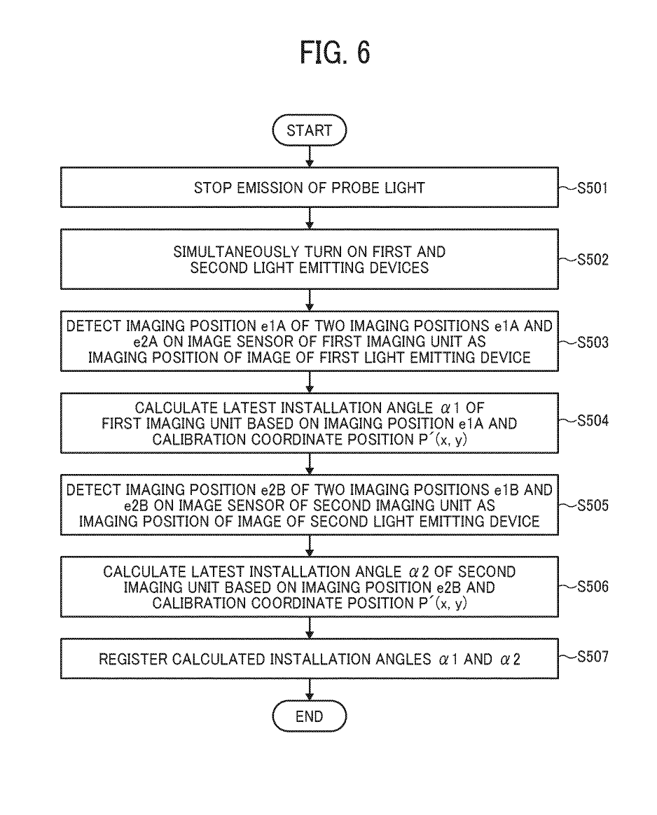

A first type of installation angle calibration process will now be described based on the flowchart of FIG. 6.

At step S501, the illumination control unit 11 first turns off the first illuminating unit 38A and the second illuminating unit 38B to stop the emission of the probe light.

At step S502, the light emission control unit 12 simultaneously turns on the first light emitting device 36A and the second light emitting device 36B. In this case, the respective images of the turned-on first light emitting device 36A and second light emitting device 36B are formed on each of the image sensor 26A of the first imaging unit 20A and the image sensor 26B of the second imaging unit 20B as bright spots.

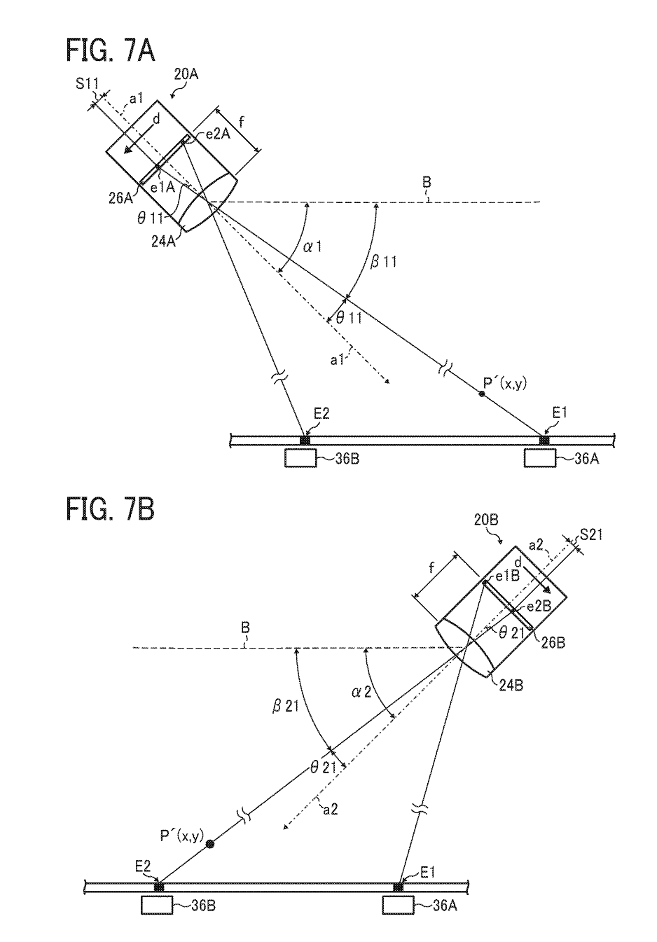

At step S503, the imaging position detecting unit 13 performs the following procedure to detect an imaging position e1A of two imaging positions e1A and e2A on the image sensor 26A of the first imaging unit 20A as the imaging position of the image of the first light emitting device 36A, as illustrated in FIG. 7A.

FIG. 7A schematically illustrates a state in which the respective images of the first light emitting device 36A and the second light emitting device 36B are formed on the image sensor 26A of the first imaging unit 20A via the image forming optical system 24A. The imaging position detecting unit 13 first performs a procedure similar to that for detecting the imaging position p1 of the image of the pointer 50 inserted in the coordinate input area, to thereby detect the imaging position e1A of the image of the first light emitting device 36A and the imaging position e2A of the image of the second light emitting device 36B each based on the peak point in the light intensity waveform of the camera output signal from the image sensor 26A of the first imaging unit 20A, i.e., the point corresponding to the bright spot.

In this case, the imaging position e1A of the image of the first light emitting device 36A is constantly in front of the imaging position e2A of the image of the second light emitting device 36B in the direction of arrow d, as illustrated in FIG. 7A. Based on this relationship between the imaging positions e1A and e2A, the imaging position detecting unit 13 detects the imaging position e1A of the two imaging positions e1A and e2A, which is located in front of the imaging position e2A in the direction of arrow d, as the imaging position of the image of the first light emitting device 36A.

At step S504, the installation angle calibrating unit 16 calculates the latest installation angle α1 of the first imaging unit 20A based on the imaging position e1A and the calibration coordinate position P′ (x, y).

A procedure of calculating the latest installation angle α1 will now be described with reference to FIG. 7A.

Herein, s11 represents the distance from the center of the image sensor 26A of the first imaging unit 20A to the center of the imaging position e1A, and f represents the focal length of the image forming optical system 24A of the first imaging unit 20A. Further, θ11 represents the angle formed by a line segment connecting the imaging position e1A and the two-dimensional coordinate position of the first light emitting device 36A and the center line of the image sensor 26A, i.e., the optical axis a1 of the image forming optical system 24A.

The angle θ11 is calculated from equation (7) given below:

θ11=tan⁻¹(s11/f) (7)

Further, an angle β11 formed by the line segment connecting the imaging position e1A and the two-dimensional coordinate position of the first light emitting device 36A and the baseline B passing through the optical center of the image forming optical system 24A of the first imaging unit 20A is calculated from equation (8) given below with the calibration coordinate position P′ (x, y) located on the line segment:

tan β11=y/x (8)

Further, the latest installation angle α1 of the first imaging unit 20A is calculated from equation (9) given below with the angles θ11 and β11 calculated by the above-described procedures:

α1=β11+θ11 (9)

At step S505, the imaging position detecting unit 13 performs a procedure similar to the above-described procedure to detect an imaging position e2B of two imaging positions e1B and e2B on the image sensor 26B of the second imaging unit 20B as the imaging position of the image of the second light emitting device 36B.

That is, when the respective images of the first light emitting device 36A and the second light emitting device 36B are formed on the image sensor 26B of the second imaging unit 20B via the image forming optical system 24B, the imaging position e2B of the image of the second light emitting device 36B is constantly in front of the imaging position e1B of the image of the first light emitting device 36A in the direction of arrow d, as illustrated in FIG. 7B. Based on this relationship between the imaging positions e1B and e2B, the imaging position detecting unit 13 detects the imaging position e2B of the two imaging positions e1B and e2B, which is located in front of the imaging position e1B in the direction of arrow d, as the imaging position of the image of the second light emitting device 36B.

At step S506, the installation angle calibrating unit 16 performs a procedure similar to the above-described procedure to calculate the latest installation angle α2 of the second imaging unit 20B based on the imaging position e2B and the calibration coordinate position P′ (x, y).

That is, as illustrated in FIG. 7B, s21 represents the distance from the center of the image sensor 26B of the second imaging unit 20B to the center of the imaging position e2B, and f represents the focal length of the image forming optical system 24B of the second imaging unit 20B. Further, θ21 represents the angle formed by a line segment connecting the imaging position e2B and the two-dimensional coordinate position of the second light emitting device 36B and the center line of the image sensor 26B, i.e., the optical axis a2 of the image forming optical system 24B. The angle θ21 is calculated from equation (10) given below:

θ21=tan⁻¹(s21/f) (10)

Further, an angle β21 formed by the line segment connecting the imaging position e2B and the two-dimensional coordinate position of the second light emitting device 36B and the baseline B passing through the optical center of the image forming optical system 24B of the second imaging unit 20B is calculated from equation (11) given below with the calibration coordinate position P′ (x, y) on the line segment and the maximum value xmax of the x-coordinates in the coordinate input area:

tan β21=y/(xmax−x) (11)

Further, the latest installation angle α1 of the second imaging unit 20B is calculated from equation (12) given below with the angles θ21 and β21 calculated by the above-described procedures:

α2=β21+θ21 (12)

Finally, at step S507, the installation angle calibrating unit 16 discards the installation angles α1 and α2 currently stored in the storage area 18, and newly registers in the storage area 18 the latest installation angles α1 and α2 calculated at steps S504 and S506, respectively.

According to the above-described first type of installation angle calibration process executed by the coordinate input apparatus 200 of the first embodiment, there is no need for synchronization of the exposure of the first imaging unit 20A and the second imaging unit 20B and the light emission of the first light emitting device 36A and the second light emitting device 36B.

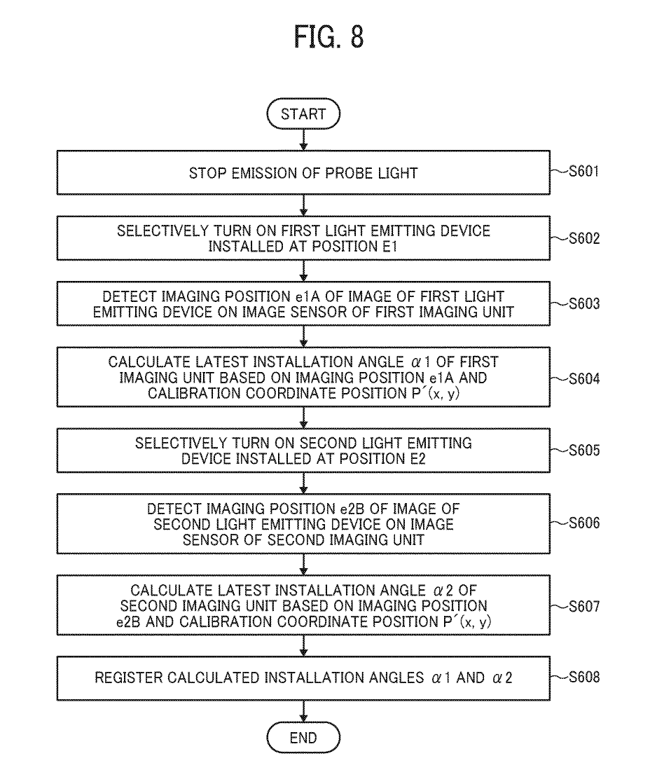

A second type of installation angle calibration process executed by the coordinate input apparatus 200 of the first embodiment will now be described based on the flowchart of FIG. 8.

At step S601, the illumination control unit 11 first turns off the first illuminating unit 38A and the second illuminating unit 38B to stop the emission of the probe light.

At step S602, the light emission control unit 12 selectively turns on only the first light emitting device 36A installed at the position E1. In this step, the second light emitting device 36B installed at the position E2 is turned off. Consequently, only the image of the turned-on first light emitting device 36A is formed on the image sensor 26A of the first imaging unit 20A as a bright spot.

At step S603, the imaging position detecting unit 13 detects the imaging position e1A of the image of the first light emitting device 36A on the image sensor 26A of the first imaging unit 20A. More specifically, the imaging position detecting unit 13 detects the imaging position e1A of the image of the first light emitting device 36A based on the peak point in the light intensity waveform of the camera output signal from the image sensor 26A of the first imaging unit 20A, i.e., the point corresponding to the bright spot.

At step S604, the installation angle calibrating unit 16 calculates the latest installation angle α1 of the first imaging unit 20A by the same procedure as that of step S504 in FIG. 6 based on the imaging position e1A and the calibration coordinate position P′ (x, y).

At step S605, the light emission control unit 12 selectively turns on only the second light emitting device 36B installed at the position E2. In this step, the first light emitting device 36A installed at the position E1 is turned off. Consequently, only the image of the turned-on second light emitting device 36B is formed on the image sensor 26B of the second imaging unit 20B as a bright spot.

At step S606, the imaging position detecting unit 13 detects the imaging position e2B of the image of the second light emitting device 36B on the image sensor 26B of the second imaging unit 20B by the same procedure as that of step S505 in FIG. 6.

At step S607, the installation angle calibrating unit 16 calculates the latest installation angle α2 of the second imaging unit 20B by the same procedure as that of step S506 in FIG. 6 based on the imaging position e2B and the calibration coordinate position P′ (x, y).

Finally, at step S608, the installation angle calibrating unit 16 discards the installation angles α1 and α2 currently stored in the storage area 18, and newly registers in the storage area 18 the latest installation angles α1 and α2 calculated at steps S604 and S607, respectively.

According to the above-described second type of installation angle calibration process, the imaging position (i.e., the bright spot) detected by the imaging position detecting unit 13 is directly used as the imaging position of the image of the target light emitting device.

As described above, according to the first embodiment, the installation angle α1 of the first imaging unit 20A and the installation angle α2 of the second imaging unit 20B are automatically calibrated without involvement of a user.

Following the above description of the first embodiment of the present invention, a second embodiment of the present invention will now be described. The following description will focus on differences from the first embodiment, with description of parts in common with those of the first embodiment omitted.

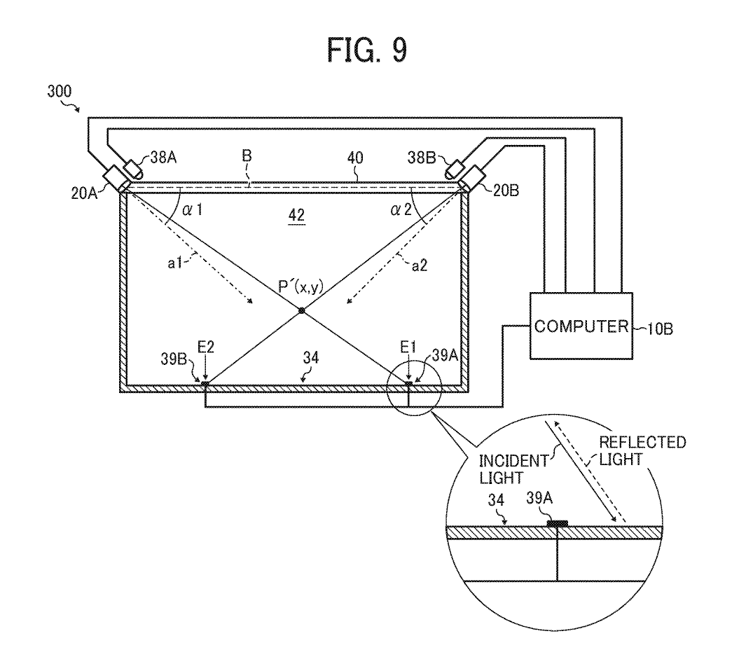

FIG. 9 schematically illustrates a configuration of a coordinate input apparatus 300 according to the second embodiment of the present invention. As illustrated in FIG. 9, the coordinate input apparatus 300 of the second embodiment is different from the coordinate input apparatus 200 of the first embodiment in including two interceptors 39, i.e., a first interceptor 39A and a second interceptor 39B, each of which is capable of intercepting a portion of the retroreflecting member 34.

In the second embodiment, each of the interceptors 39 is a member installed at a position on the retroreflecting member 34 to prevent the probe light from being reflected to the first imaging unit 20A and the second imaging unit 20B, and may be a mechanical shutter including a rotary plate or an optical shutter including an optical device such as a polarizing plate and liquid crystal.

In the second embodiment, the first interceptor 39A and the second interceptor 39B are installed at respective predetermined positions around the peripheral portion of the coordinate input area. Specifically, as illustrated in FIG. 9, the first interceptor 39A is installed to be capable of intercepting the position E1, which is on the straight line passing through the optical center of the first imaging unit 20A and the calibration coordinate position P′ (x, y) and is around the peripheral portion of the coordinate input area. Further, the second interceptor 39B is installed to be capable of intercepting the position E2, which is on the straight line passing through the optical center of the second imaging unit 20B and the calibration coordinate position P′ (x, y) and is around the peripheral portion of the coordinate input area.

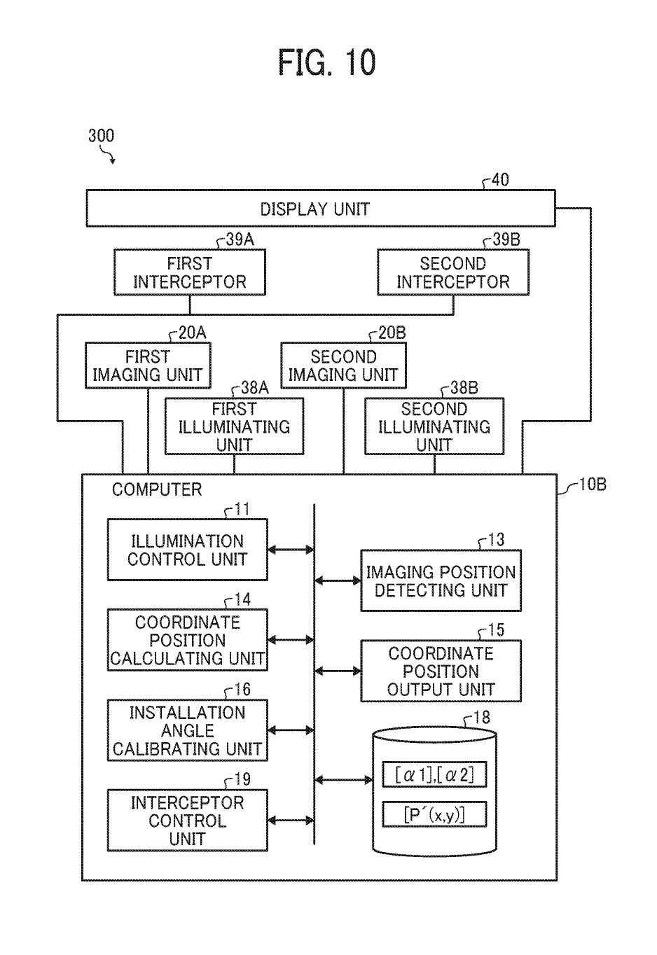

FIG. 10 illustrates functional blocks of the coordinate input apparatus 300 of the second embodiment. As illustrated in FIG. 10, a computer 10B forming the coordinate input apparatus 300 of the second embodiment is different from the foregoing computer 10 forming the coordinate input apparatus 200 of the first embodiment in including an interceptor control unit 19 that controls the first interceptor 39A and the second interceptor 39B in place of the light emission control unit 12 of the coordinate input apparatus 200.

A coordinate position calculation process executed by the coordinate input apparatus 300 of the second embodiment is the same as that of the first embodiment described above with reference to FIG. 4, and thus a description thereof will be omitted here. The following description will be given of an installation angle calibration process executed by the coordinate input apparatus 300.

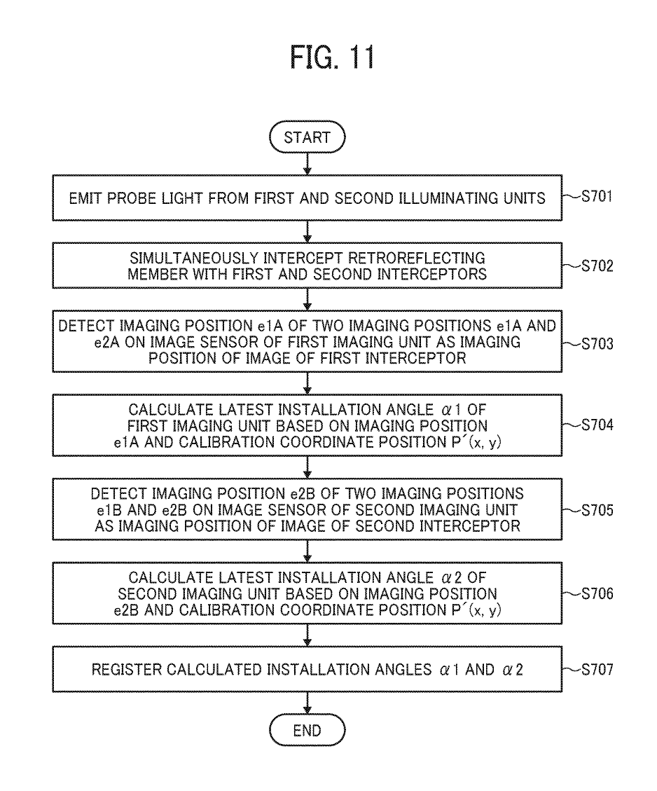

Similarly as in the first embodiment, the installation angle calibration process of the second embodiment has two types. A first type of installation angle calibration process will first be described based on the flowchart of FIG. 11.

At step S701, the illumination control unit 11 first turns on the first illuminating unit 38A and the second illuminating unit 38B to emit the probe light therefrom.

At step S702, the interceptor control unit 19 controls the first interceptor 39A and the second interceptor 39B to simultaneously intercept the positions E1 and E2 on the retroreflecting member 34. In this case, respective images of the first interceptor 39A and the second interceptor 39B not reflecting the probe light are formed on each of the image sensor 26A of the first imaging unit 20A and the image sensor 26B of the second imaging unit 20B as dark spots.

At step S703, the imaging position detecting unit 13 detects the imaging position e1A of the two imaging positions e1A and e2A on the image sensor 26A of the first imaging unit 20A as the imaging position of the image of the first interceptor 39A by the same procedure as that of the first embodiment.

At step S704, the installation angle calibrating unit 16 calculates the latest installation angle α1 of the first imaging unit 20A by the same procedure as that of the first embodiment based on the imaging position e1A and the calibration coordinate position P′ (x, y).

At step S705, the imaging position detecting unit 13 detects the imaging position e2B of the two imaging positions e1B and e2B on the image sensor 26B of the second imaging unit 20B as the imaging position of the image of the second interceptor 39B by the same procedure as that of the first embodiment.

At step S706, the installation angle calibrating unit 16 calculates the latest installation angle α2 of the second imaging unit 20B by the same procedure as that of the first embodiment based on the imaging position e2B and the calibration coordinate position P′ (x, y).

Finally, at step S707, the installation angle calibrating unit 16 discards the installation angles α1 and α2 currently stored in the storage area 18, and newly registers in the storage area 18 the latest installation angles α1 and α2 calculated at steps S704 and S706, respectively.

According to the above-described first type of installation angle calibration process executed by the coordinate input apparatus 300 of the second embodiment, there is no need for synchronization of the exposure of the first imaging unit 20A and the second imaging unit 20B and the control of the first interceptor 39A and the second interceptor 39B.

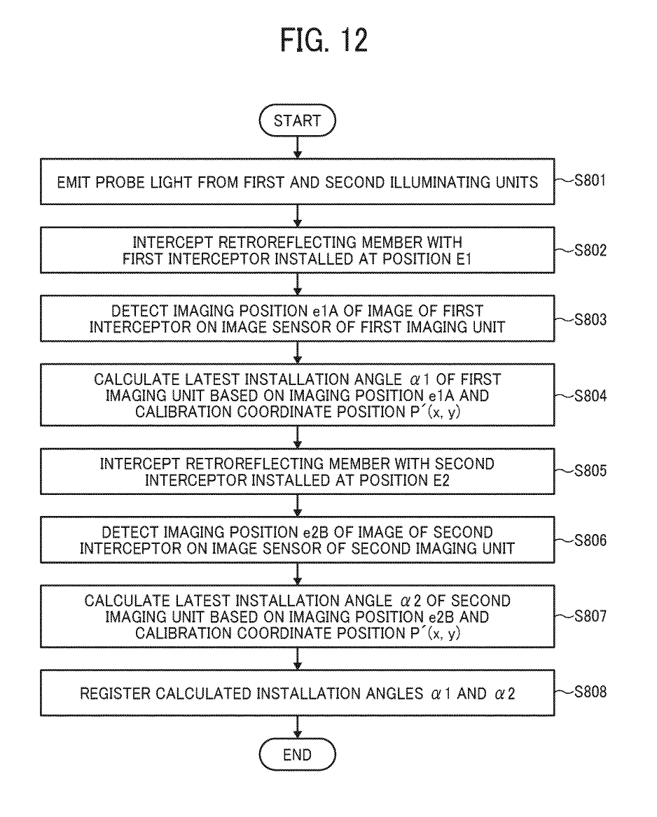

A second type of installation angle calibration process executed by the coordinate input apparatus 300 of the second embodiment will now be described based on the flowchart of FIG. 12.

At step S801, the illumination control unit 11 first turns on the first illuminating unit 38A and the second illuminating unit 38B to emit the probe light therefrom.

At step S802, the interceptor control unit 19 controls the first interceptor 39A to selectively intercept only the position E1 on the retroreflecting member 34. In this step, the second interceptor 39B does not intercept the position E2 on the retroreflecting member 34. Consequently, only the image of the first interceptor 39A not reflecting the probe light is formed on the image sensor 26A of the first imaging unit 20A as a dark spot.

At step S803, the imaging position detecting unit 13 detects the imaging position e1A of the image of the first interceptor 39A on the image sensor 26A of the first imaging unit 20A by the same procedure as that of the first embodiment.

At step S804, the installation angle calibrating unit 16 calculates the latest installation angle α1 of the first imaging unit 20A by the same procedure as that of the first embodiment based on the imaging position e1A and the calibration coordinate position P′ (x, y).

At step S805, the interceptor control unit 19 controls the second interceptor 39B to selectively intercept only the position E2 on the retroreflecting member 34. In this step, the first interceptor 39A does not intercept the position E1 on the retroreflecting member 34. Consequently, only the image of the second interceptor 39B not reflecting the probe light is formed on the image sensor 26B of the second imaging unit 20B as a dark spot.

At step S806, the imaging position detecting unit 13 detects the imaging position e2B of the image of the second interceptor 39B on the image sensor 26B of the second imaging unit 20B by the same procedure as that of the first embodiment.

At step S807, the installation angle calibrating unit 16 calculates the latest installation angle α2 of the second imaging unit 20B by the same procedure as that of the first embodiment based on the imaging position e2B and the calibration coordinate position P′ (x, y).

Finally, at step S808, the installation angle calibrating unit 16 discards the installation angles α1 and α2 currently stored in the storage area 18, and newly registers in the storage area 18 the latest installation angles α1 and α2 calculated at steps S804 and S807, respectively.

The respective functions of each of the foregoing embodiments may be implemented by a program described in C, C++, C#, or Java (registered trademark), for example. Further, the program of each of the embodiments may be distributed as stored in a recording medium, such as a hard disk device, a compact disc-ROM (CD-ROM), a magneto-optical (MO) disc, a digital versatile disk (DVD), a flexible disk, an electrically erasable programmable ROM (EEPROM), or an erasable programmable ROM (EPROM), for example, or may be transmitted via a network in a format readable by another apparatus.

The above-described embodiments are illustrative and do not limit the present invention. Thus, numerous additional modifications and variations are possible in light of the above teachings. For example, elements and/or features of different illustrative embodiments may be combined with each other and/or substituted for each other within the scope of the present invention. Further, the above-described steps are not limited to the order disclosed herein.

Each of the functions of the described embodiments may be implemented by one or more processing circuits or circuitry. Processing circuitry includes a programmed processor, as a processor includes circuitry. A processing circuit also includes devices such as an application specific integrated circuit (ASIC), digital signal processor (DSP), field programmable gate array (FPGA), and conventional circuit components arranged to perform the recited functions.

1. A coordinate input apparatus comprising:
an imaging circuit including an image sensor, and disposed on a baseline parallel to one side of a peripheral portion of a two-dimensional coordinate input area including a calibration coordinate position virtually defined for calibration, with an optical axis of the imaging circuit forming a predetermined installation angle with the baseline;
a retroreflecting member disposed along the peripheral portion of the coordinate input area;
an illuminating unit disposed at a same position as a position of the imaging circuit to emit light traveling through the coordinate input area toward the retroreflecting member;
a light emitting device disposed around the peripheral portion of the coordinate input area on a straight line passing through an optical center of the imaging circuit and the calibration coordinate position; and
circuitry to control turn-on and turn-off of the illuminating unit and the light emitting device, respectively,
the circuitry being configured to
detect, when a specific two-dimensional coordinate position in the coordinate input area is pointed by a pointer, an imaging position of an image of the pointer on the image sensor of the imaging circuit,
calculate the specific two-dimensional coordinate position in the coordinate input area by triangulation based on the imaging position and the installation angle, and
calibrate the installation angle of the imaging circuit based on the imaging position and the calibration coordinate position.

2. The coordinate input apparatus of claim 1, wherein the imaging circuit includes a first imaging circuit and a second imaging circuit spaced from each other,
wherein the illuminating unit includes a first illuminating unit corresponding to the first imaging circuit and a second illuminating unit corresponding to the second imaging circuit,
wherein the light emitting device includes a first light emitting device corresponding to the first illuminating unit and a second light emitting device corresponding to the second illuminating unit, and
wherein the circuitry individually controls turn-on and turn-off of the first light emitting device and turn-on and turn-off of the second light emitting device.

3. The coordinate input apparatus of claim 2, wherein, during the calibration, the circuitry turns off the first illuminating unit and the second illuminating unit,
selectively turns on the first light emitting device and the second light emitting device,
detects an imaging position of an image of the turned-on first light emitting device on the image sensor of the first imaging circuit as a first imaging position,
detects an imaging position of an image of the turned-on second light emitting device on the image sensor of the second imaging circuit as a second imaging position,
calibrates the installation angle of the first imaging circuit based on the first imaging position and the calibration coordinate position, and
calibrates the installation angle of the second imaging circuit based on the second imaging position and the calibration coordinate position.

4. The coordinate input apparatus of claim 2, wherein, during the calibration, the circuitry turns off the first illuminating unit and the second illuminating unit,
simultaneously turns on the first light emitting device and the second light emitting device,
detects one of an imaging position of an image of the turned-on first light emitting device and an imaging position of an image of the turned-on second light emitting device on the image sensor of the first imaging circuit as a first imaging position,
detects one of an imaging position of an image of the turned-on first light emitting device and an imaging position of an image of the turned-on second light emitting device on the image sensor of the second imaging circuit as a second imaging position,
calibrates the installation angle of the first imaging circuit based on the first imaging position and the calibration coordinate position, and
calibrates the installation angle of the second imaging circuit based on the second imaging position and the calibration coordinate position.

5. The coordinate input apparatus of claim 3, wherein, during the calibration, the circuitry selectively turns on the first light emitting device, and then detects the imaging position of the image of the turned-on first light emitting device on the image sensor of the first imaging circuit as the first imaging position, and
the circuitry selectively turns on the second light emitting device, and then detects the imaging position of the image of the turned-on second light emitting device on the image sensor of the second imaging circuit as the second imaging position.

6. A coordinate input apparatus comprising:
an imaging circuit including an image sensor, and disposed on a baseline parallel to one side of a peripheral portion of a two-dimensional coordinate input area including a calibration coordinate position virtually defined for calibration, with an optical axis of the imaging circuit forming a predetermined installation angle with the baseline;
a retroreflecting member disposed along the peripheral portion of the coordinate input area;
an illuminating unit disposed at a same position as a position of the imaging circuit to emit light traveling through the coordinate input area toward the retroreflecting member;
an interceptor disposed around the peripheral portion of the coordinate input area to intercept a position on the retroreflecting member intersecting a straight line passing through an optical center of the imaging circuit and the calibration coordinate position; and
a circuitry to control turn-on and turn-off of the illuminating unit and the interceptor, respectively,
the circuitry being configured to
detect, when a specific two-dimensional coordinate position in the coordinate input area is pointed by a pointer, an imaging position of an image of the pointer on the image sensor of the imaging circuit,
calculate the specific two-dimensional coordinate position in the coordinate input area by triangulation based on the imaging position and the installation angle, and
calibrate the installation angle of the imaging circuit based on the imaging position and the calibration coordinate position.

7. The coordinate input apparatus of claim 6, wherein the imaging circuit includes a first imaging circuit and a second imaging circuit spaced from each other,
wherein the illuminating unit includes a first illuminating unit corresponding to the first imaging circuit and a second illuminating unit corresponding to the second imaging circuit, and
wherein the interceptor includes a first interceptor to selectively intercept a first position on the straight line passing through the optical center of the first imaging circuit and the calibration coordinate position, and a second interceptor to selectively intercept a second position on the straight line passing through the optical center of the second imaging circuit and the calibration coordinate position.

8. The coordinate input apparatus of claim 7, wherein, during the calibration, the circuitry controls the first interceptor and the second interceptor to intercept the first position and the second position,
detects an imaging position of an image of the first interceptor on the image sensor of the first imaging circuit as a first imaging position,
detects an imaging position of an image of the second interceptor on the image sensor of the second imaging circuit as a second imaging position,
calibrates the installation angle of the first imaging circuit based on the first imaging position and the calibration coordinate position, and
calibrates the installation angle of the second imaging circuit based on the second imaging position and the calibration coordinate position.

9. A coordinate position calculating method executed by a coordinate input apparatus, the coordinate input apparatus comprising:
an imaging circuit including an image sensor, and disposed on a baseline parallel to one side of a peripheral portion of a two-dimensional coordinate input area including a calibration coordinate position virtually defined for calibration, with an optical axis of the imaging circuit forming a predetermined installation angle with the baseline;
a retroreflecting member disposed along the peripheral portion of the coordinate input area;
an illuminating unit disposed at a same position as a position of the imaging circuit to emit light traveling through the coordinate input area toward the retroreflecting member; and
a light emitting device disposed around the peripheral portion of the coordinate input area on a straight line passing through an optical center of the imaging circuit and the calibration coordinate position, and
the coordinate position calculating method comprising:
controlling turn-on and turn-off of the illuminating unit;
controlling turn-on and turn-off of the light emitting device;
detecting, when a specific two-dimensional coordinate position in the coordinate input area is pointed by a pointer, an imaging position of an image of the pointer on the image sensor of the imaging circuit;
calculating the specific two-dimensional coordinate position in the coordinate input area by triangulation based on the imaging position and the installation angle; and
calibrating the installation angle of the imaging circuit based on the imaging position and the calibration coordinate position.

10. The coordinate position calculating method of claim 9, wherein the imaging circuit includes a first imaging circuit and a second imaging circuit spaced from each other,
wherein the illuminating unit includes a first illuminating unit corresponding to the first imaging circuit and a second illuminating unit corresponding to the second imaging circuit,
wherein the light emitting device includes a first light emitting device corresponding to the first illuminating unit and a second light emitting device corresponding to the second illuminating unit, and
wherein the controlling turn-on and turn-off of the light emitting device individually controls turn-on and turn-off of the first light emitting device and turn-on and turn-off of the second light emitting device.

11. The coordinate position calculating method of claim 10, wherein, during the calibration,
the controlling turn-on and turn-off of the illuminating unit turns off the first illuminating unit and the second illuminating unit,
the controlling turn-on and turn-off of the light emitting device selectively turns on the first light emitting device and the second light emitting device,
the detecting detects an imaging position of an image of the turned-on first light emitting device on the image sensor of the first imaging circuit as a first imaging position, and detects an imaging position of an image of the turned-on second light emitting device on the image sensor of the second imaging circuit as a second imaging position, and
the calibrating calibrates the installation angle of the first imaging circuit based on the first imaging position and the calibration coordinate position, and calibrates the installation angle of the second imaging circuit based on the second imaging position and the calibration coordinate position.
